(19) United States
(12) Patent Application Publication
(10) Pub. No.: US 2014/0332437 A1
(43) Pub. Date: Nov. 13, 2014

(54) FOOD CONTAINER HAVING IMPROVED OXYGEN BARRIER PROPERTIES AND MANUFACTURING METHED THEREOF

(71) Applicants: CJ CHEILJEDANG CORPORATION, Seoul (KR); KOREA INSTITUTE OF SCIENCE AND TECHNOLOGY, Seoul (KR)

(72) Inventors: Kwang Ryeol Lee, Seoul (KR); Myoung Woon Moon, Seoul (KR); Seong Jin Kim, Anseong-si (KR); Eun Kyung Song, Goyang-si (KR); Kyoung Sik Jo, Seoul (KR); Tae Kyung Yun, Seoul (KR)

(21) Appl. No.: 14/372,200

(22) PCT Filed: Feb. 28, 2013
(86) PCT No.: PCT/KR2013/001618

§ 371 Date: Jul. 14, 2014

(30) Foreign Application Priority Data
Feb. 28, 2012 (KR) 10-2012-0020243

(51) Int. Cl. B65D 81/24; C23C 16/40; B65D 25/14

(52) U.S. Cl. CPC B65D 81/24; B65D 25/14; C23C 16/402
USPC 206/524.2; 427/569; 427/579

(57) ABSTRACT

There are provided a food container having improved oxygen barrier properties and a manufacturing method thereof. The food container includes a container made of a plastic material, a buffer thin layer formed on a surface of the container and having a thickness of 5 to 30 nm, and an oxygen barrier thin layer formed on the buffer thin layer. Accordingly, it is possible to provide a food container and a manufacturing method thereof, which can remarkably improve oxygen barrier properties by depositing, using a plasma method, an oxygen barrier thin layer on a porous plastic container having low surface energy without breaking the oxygen barrier thin layer.

### CROSS-REFERENCE TO RELATED APPLICATIONS

This application is a national stage of International Application No. PCT/KR2013/001618, filed Feb. 28, 2013, which claims the benefit of Korean Application No. 10-2012-0020243, filed Feb. 28, 2012, in the Korean Intellectual Property. All disclosures of the document(s) named above are incorporated herein by reference.

### BACKGROUND OF THE INVENTION

1. Field of the Invention

An aspect of the present invention relates to a food container and a manufacturing method thereof, and more particularly, to a food container and a manufacturing method thereof, which can remarkably improve oxygen barrier properties by depositing, using a plasma method, an oxygen barrier thin layer on a porous plastic container having low surface energy without breaking the oxygen barrier thin layer.

2. Description of the Related Art

In order to keep perishable foods for a long period of time, it is very important to provide oxygen barrier performance to food containers.

Plastic food containers have advantages of low cost of production and easiness of mass production, but have a disadvantage that oxygen properties are remarkably lowered by a porous structure that is a unique feature of plastic.

In order to solve such a disadvantage, studies on a technique for coating a thin layer on a plastic food container using a plasma method has been conducted.

However, the result of such studies is limited to only plastic having a relatively high surface energy (0.031 to 0.047 N/m, Accu dyne test), such as polyethylene terephthalate (PET), but does not achieve the desired effect from plastic having a low surface energy (0.023 to 0.038 N/m, Accu dyne test), such as polypropylene (PP).

It is known that this results from properties of the PP that is more porous than the PET [Reference document: N. Inagaki, et al., Journal of Applied Polymer Science 78 (2000) 2389-2397].

Consequently, while the PET has a property that as the thickness of a thin layer deposited on a surface of the PET is increased, oxygen barrier properties are increased, the PP has a property that although the thickness of a thin layer deposited on a surface of the PP is increased, oxygen barrier properties are not improved [Reference document: D. S. Finch, et al., Packaging Technology and Science 9 (1996) 73-85].

This is because the thin layer deposited on the surface of the PP is not well adhered to the surface of the PP due to its low surface energy and porous structure, but is taken off or broken.

For this reason, products to which the oxygen barrier properties are added by coating a thin layer on the PP using a plasma method could not be produced. However, the PP has advantages such as price competitiveness, thermal resistance and stability against endocrine disrupting chemicals as compared with other plastic materials. Hence, when the PP having the oxygen barrier properties is applied to food containers, it is expected that the PP will have a great economic value.

### SUMMARY OF THE INVENTION

### Technical Problem

Accordingly, an object of the present invention is to provide a food container and a manufacturing method thereof, which can remarkably improve oxygen barrier properties by depositing, using a plasma method, an oxygen barrier thin layer on a porous plastic container having low surface energy without breaking the oxygen barrier thin layer.

### Technical Solution

According to an aspect of the present invention, there is provided a food container having improved oxygen barrier properties, including: a container made of a plastic material; a buffer thin layer formed on a surface of the container and having a thickness of 5 to 30 nm; and an oxygen barrier thin layer formed on the buffer thin layer.

The thickness of the oxygen barrier thin layer is 25 to 50 mm.

A plasma pretreatment may be performed on the surface of the container so as to improve the adhesion between the surface of the container and the buffer thin layer.

The container may be formed of polypropylene (PP).

The buffer thin layer may be formed of hexamethyldisiloxane (HMDSO) or silicon (Si).

The oxygen barrier thin layer may be formed of silicon oxide.

The food container may further include a functional thin layer formed on the oxygen barrier thin layer.

The functional thin layer may be formed of HMDSO or fluorine incorporated diamond like carbon (F-DLC).

According to another aspect of the present invention, there is provided a manufacturing method of a food container having improved oxygen barrier properties, the method including the steps of: (a) preparing a container made of a plastic material; (b) performing an oxygen plasma treatment on a surface of the container; (c) depositing a buffer thin layer having a thickness of 5 to 30 nm on the surface of the container; and (d) depositing an oxygen barrier thin layer on the buffer thin layer.

The thickness of the oxygen barrier thin layer is 25 to 50 mm.

The container may be formed of PP.

The steps (c) and (d) may be performed through plasma chemical vapor deposition.

The buffer thin layer may be formed of HMDSO or Si.

The oxygen barrier thin layer may be formed of silicon oxide.

The method may further include the step of (e) depositing a functional thin layer on the oxygen barrier thin layer.

The functional thin layer may be formed of HMDSO or F-DLC.

### Advantageous Effects

As described above, according to the present invention, it is possible to provide a food container and a manufacturing method thereof, which can remarkably improve oxygen barrier properties by depositing, using a plasma method, an oxygen barrier thin layer on a porous plastic container having low surface energy without breaking the oxygen barrier thin layer.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a sectional view showing a food container according to a first embodiment of the present invention;

FIG. 2 is a sectional view illustrating a manufacturing method of the food container shown in FIG. 1;

FIG. 3 is a graph comparing oxygen barrier properties of a specimen on which a plasma pretreatment is not performed and a specimen on which the plasma treatment is performed;

FIG. 4 is a graph showing oxygen barrier properties changed as the thicknesses of a buffer thin layer and an oxygen barrier thin layer are changed;

FIG. 5 is a scanning electron microscope (SEM) photograph showing structures of a surface of the food container, which are changed as the thickness of the buffer thin layer is increased, when the thickness of the oxygen barrier thin layer is 30 nm in the experimental result of FIG. 4;

FIG. 6 is a sectional view showing a food container according to a second embodiment of the present invention; and

FIG. 7 is a sectional view illustrating a manufacturing method of the food container shown in FIG. 6.

### DETAILED DESCRIPTION OF THE EMBODIMENTS

Hereinafter, preferred embodiments of the present invention will be described in detail with reference to the accompanying drawings. However, the present invention is not limited to the embodiments but may be implemented into different forms. These embodiments are provided only for illustrative purposes and for full understanding of the scope of the present invention by those skilled in the art. Throughout the drawings, like elements are designated by like reference numerals.

Hereinafter, a food container having improved oxygen barrier properties and a manufacturing method thereof according to embodiments of the present invention will be described with reference to the accompanying drawings.

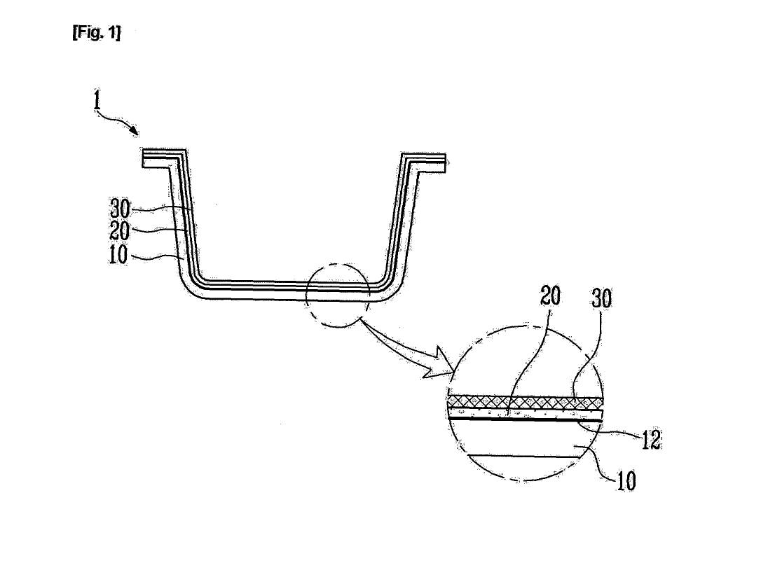

FIG. 1 is a sectional view showing a food container according to a first embodiment of the present invention.

Referring to FIG. 1, the food container 1 having improved oxygen barrier properties (hereinafter, referred to as the “food container”) according to the first embodiment of the present invention includes a container 10, a buffer thin layer 20 and an oxygen barrier thin layer 30.

The container 10 may have a predetermined accommodation space in which foods are contained, and is formed of a plastic material.

The container 10 is preferably formed of a material such as polypropylene (PP), which has low surface energy and is porous, but may be formed of another plastic material which has a lower surface energy and is more porous than the PP. The container 10 may also be formed of a plastic material such as polyethylene terephthalate (PET), which has high surface energy.

The buffer thin layer 20 is formed on a surface 12 of the container 10, and preferably has a thickness of 5 to 30 nm so as to implement optimum oxygen barrier properties.

The buffer thin layer 20 is preferably formed of hexamethyldisiloxane (HMDSO), but may be formed of silicon (Si).

In this case, a plasma pretreatment is preferably performed on the surface 12 of the container 10, on which the buffer thin layer 20 is formed, so as to improve the adhesion between the surface 12 of the container 10 and the buffer thin layer 20.

The oxygen barrier thin layer 30 is formed on the buffer thin layer 20, and preferably has a thickness of 25 to 50 nm so as to implement the optimum oxygen barrier properties.

The oxygen barrier thin layer 30 is preferably formed of silicon oxide (SiOx).

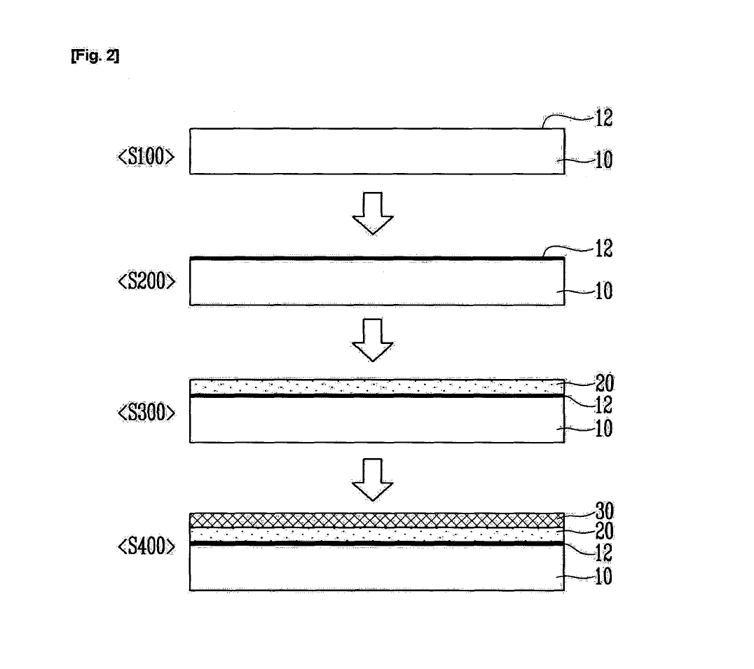

FIG. 2 is a sectional view illustrating a manufacturing method of the food container shown in FIG. 1.

Referring to FIG. 2, the manufacturing method of the food container 1 according to the first embodiment of the present invention includes a container preparation step (S100), a plasma pretreatment step (S200), a buffer thin layer deposition step (S300) and an oxygen barrier thin layer deposition step (S400).

In the container preparation step (S100), a container 10 made of a plastic material is prepared.

In this case, the container 10 is preferably formed of PP having low surface energy and large porosity. However, it is difficult that a thin layer is adhered to the PP.

Accordingly, in the plasma pretreatment step (S200), an oxygen plasma treatment is performed on a surface 12 of the container 10 before a buffer thin layer 20 is deposited on the surface 12 of the container 10.

Specifically, the plasma pretreatment step (S200) will be described. First, the container 10 made of a PP material is placed in a chamber of a radio frequency-chemical vapor deposition (RF-CVD) apparatus (not shown), and a vacuum state is formed in the chamber through a pump or the like.

Then, oxygen gas is injected into the chamber at a certain flow rate, and a plasma state is formed by applying RF-power to the chamber, thereby performing a plasma pretreatment process.

As the plasma state is formed, a self-bias voltage is generated in the chamber, and accordingly, oxygen particles having energy react with the surface 12 of the container 10.

The surface energy of the container 10 is increased by a chemical reaction between oxygen and the surface 12 of the container 10.

Therefore, the adhesion between the container 10 and the buffer thin layer 20 to be formed in the subsequent buffer thin layer deposition step (S300) may be increased, and oxygen barrier properties may also be increased.

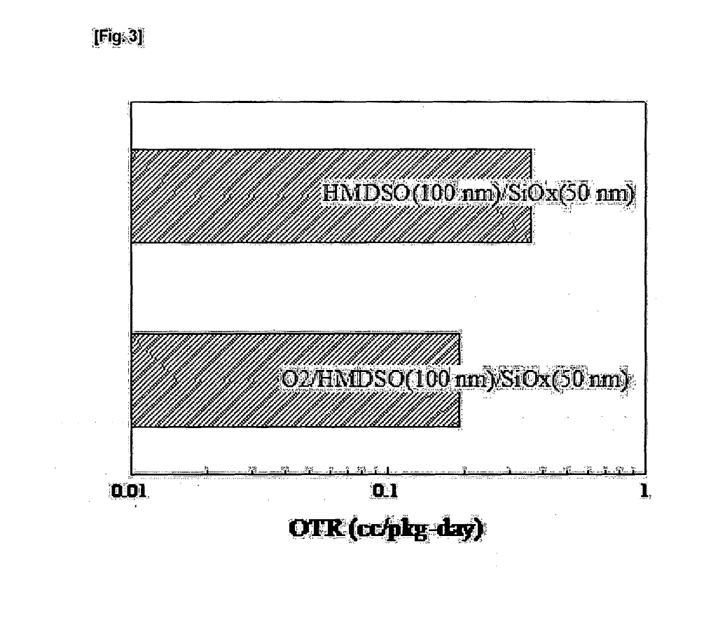

Referring to FIG. 3 in which the oxygen barrier properties of a specimen (HMDSO (100 nm)/SiOx (50 nm)) on which the plasma pretreatment is not performed and a specimen (O₂/HMDSO (100 nm)/SiOx (50 nm)) on which the plasma pretreatment is performed, it can be seen that the oxygen barrier properties of the specimen on which the plasma pretreatment is performed is higher than those of the specimen on which the plasma pretreatment is not performed (the oxygen transmission rate (OTR) of the specimen on which the plasma pretreatment is performed is lower than that of the specimen on which the plasma pretreatment is not performed).

This is because when the plasma pretreatment is not performed on the surface 12 of the container 10, the thin layer is not well deposited on the surface 12 of the container 10. Therefore, the quality of the thin layer is deteriorated, and the oxygen barrier properties are lowered.

In the buffer thin layer deposition step (S300), the buffer thin layer 20 is deposited on the surface 12 of the container 10, on which the plasma pretreatment has been performed.

The buffer thin layer 20 does not provide a mechanical deformation of the container 10 directly to an oxygen barrier thin layer 30 to be deposited on the buffer thin layer 20 but absorbs the mechanical deformation of the container 10.

The buffer thin layer 20 is a thin layer that is relatively well deformed due to its low Young's modulus, and may be formed of a material such as HMDSO or Si.

Specifically, the buffer thin layer deposition step (S300) will be described. After the plasma pretreatment step (S200) is performed, a plasma state is formed by injecting HMDSO gas into the chamber of the RF-CVD apparatus.

The buffer thin layer 20 made of a plasma-polymerized HMDSO (pp-HMDSO) may be formed material may be formed on the surface 12 of the container 10 by means of the reaction between plasma and the HMDSO gas.

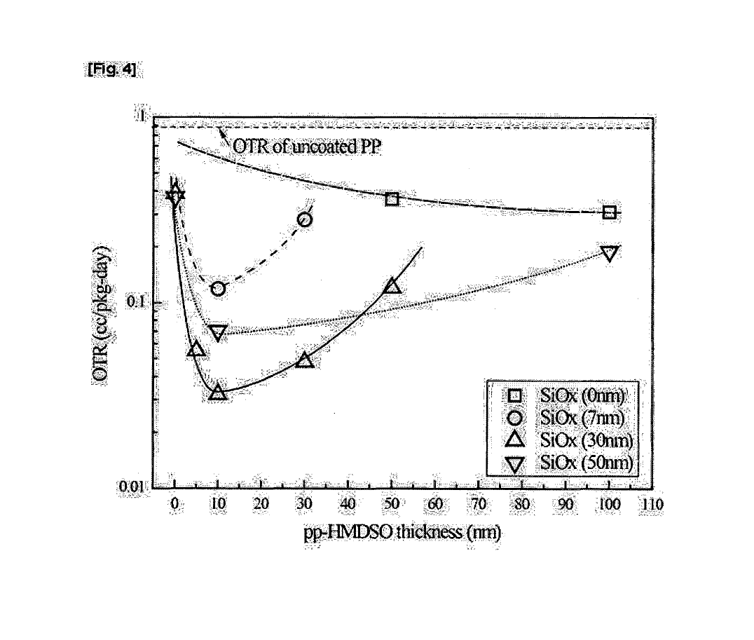

FIG. 4 is a graph showing oxygen barrier properties changed as the thicknesses of the buffer thin layer and the oxygen barrier thin layer are changed, in which there exist ‘optimum thicknesses’ of the buffer thin layer 20 and the oxygen barrier thin layer 30 for obtaining excellent oxygen barrier properties.

Particularly, the graph of FIG. 4 shows a result obtained by performing an experiment using the buffer thin layer 20 made of the pp-HMDSO material and the oxygen barrier thin layer 30 made of the SiOx material.

Referring to FIG. 4, the buffer thin layer 20 preferably has a thickness of 5 to 30 nm.

If the thickness of the buffer thin layer 20 is too thin, the buffer thin layer 20 does not sufficiently perform a buffering function. If the thickness of the buffer thin layer 20 is too thick, the breakdown of the oxygen barrier thin layer 30 is caused by the compression energy of the buffer thin layer 20, and therefore, the oxygen barrier properties may be lowered.

As shown in FIG. 4, it can be seen that when the buffer thin layer 20 is formed to a thickness of 5 to 30 nm, the oxygen barrier properties are superior to those when the buffer thin layer 20 is formed to other thicknesses.

Particularly, if the buffer thin layer 20 is formed to a thickness of about 8 to 10 nm when the oxygen barrier thin layer 30 made of the SiOx material is formed to a thickness of 30 nm, the buffer thin layer 20 has an OTR of 0.03 cc/pkg, which is remarkably low, and thus high oxygen barrier properties can be implemented.

If the buffer thin layer 20 is formed to a thickness of about 8 to 10 nm when the oxygen barrier thin layer 30 made of the SiOx material is formed to a thickness of 50 nm, the buffer thin layer 20 also has an OTR of 0.07 cc/pkg, which is remarkably low, and thus high oxygen barrier properties can be implemented.

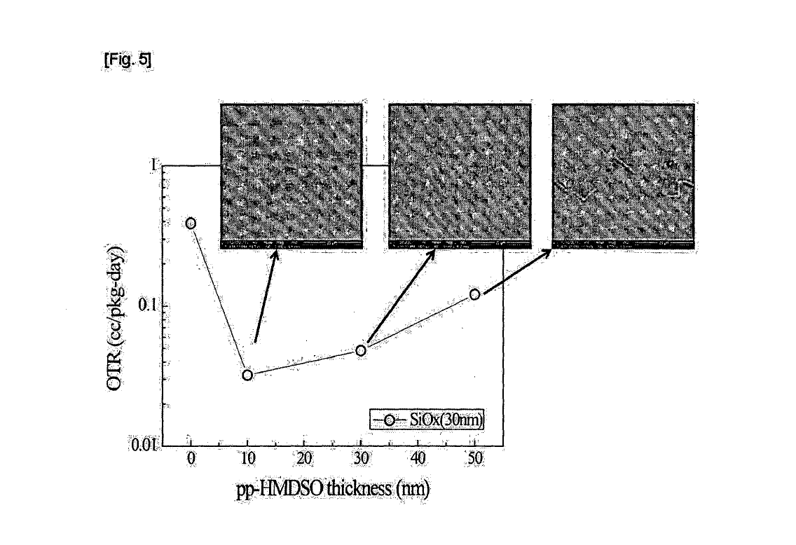

FIG. 5 is a scanning electron microscope (SEM) photograph showing structures of a surface of the food container, which are changed as the thickness of the buffer thin layer is increased, when the thickness of the oxygen barrier thin layer is 30 nm in the experimental result of FIG. 4.

Referring to FIG. 5, when the buffer thin layer 20 made of the pp-HMDSO material has a thickness of 8 to 10 nm, cracks of the oxygen barrier thin layer 30 are minimized, so that the oxygen barrier thin layer 30 has the most excellent oxygen barrier properties. When the thickness of the buffer thin layer 20 is increased to 30 nm, slight cracks are produced in the oxygen barrier thin layer 30, and therefore, the oxygen barrier properties are slightly lowered.

However, when the thickness of the buffer thin layer 20 is increased to 50 nm, the cracks of the oxygen barrier thin layer 30 become serious due to the compression energy of the buffer thin layer 20, and accordingly, the oxygen barrier properties are rapidly deteriorated.

In the oxygen barrier thin layer deposition step (S400), the oxygen barrier thin layer 30 is deposited on the buffer thin layer 20.

The oxygen barrier thin layer 30 is a thin layer having high density, and allows oxygen molecules not to penetrate into the food container 1.

Generally, it is known that as the thickness of the oxygen barrier thin layer 30 deposited on the plastic material such as the PET is increased, the oxygen barrier properties are improved. However, as the thickness of the oxygen barrier thin layer 30 deposited on the plastic material such as the PP is increased, the oxygen barrier properties are not improved.

The reason is that if the thickness of the oxygen barrier thin layer 30 deposited on the PP is too thick, the adhesion between the oxygen barrier thin layer 30 and the PP is not excellent, and therefore, the oxygen barrier thin layer 30 is broken.

As can be seen in FIG. 4, the thickness of the oxygen barrier thin layer 30 is preferably set to 25 to 50 nm in order to satisfy the condition described above.

That is, when the thickness of the oxygen barrier thin layer 30 is set to 25 to 50 nm, it is possible to achieve an OTR of 0.1 cc/pkg or less. The OTR of 0.1 cc/pkg or less is ten times lower than that of the PP, which shows oxygen barrier properties that enable food contained in the container 10 to be kept for a long period of time.

Particularly, as can be seen in FIG. 4, the thickness of the oxygen barrier thin layer 30 may be set to about 30 nm, preferably 25 to 35 nm.

The SiOx is preferably used as the material of the oxygen barrier thin layer 30.

Specifically, the oxygen barrier thin layer deposition step (S400) will be described. After the buffer thin layer deposition step (S300) is performed, the oxygen barrier thin layer 30 made of the SiOx material may be formed on the buffer thin layer 20 by injecting a small amount of oxygen gas and a large amount of HMDSO gas into the chamber of the RF-CVD apparatus and then performing a plasma reaction.

Conventionally, a method was used in which the oxygen barrier properties were improved by allowing high-priced ethylene vinyl alcohol (EVOH) to be mixed with or adhered to the PP. However, in the present invention, the EVOH is not used, so that manufacturing cost can be reduced, thereby securing price competitiveness.

In the method using the EVOH, a large amount of substance except the PP is contained in a food container, and therefore, it is difficult to recycle the food container. However, in the present invention using the plasma method, the food container can be easily recycled.

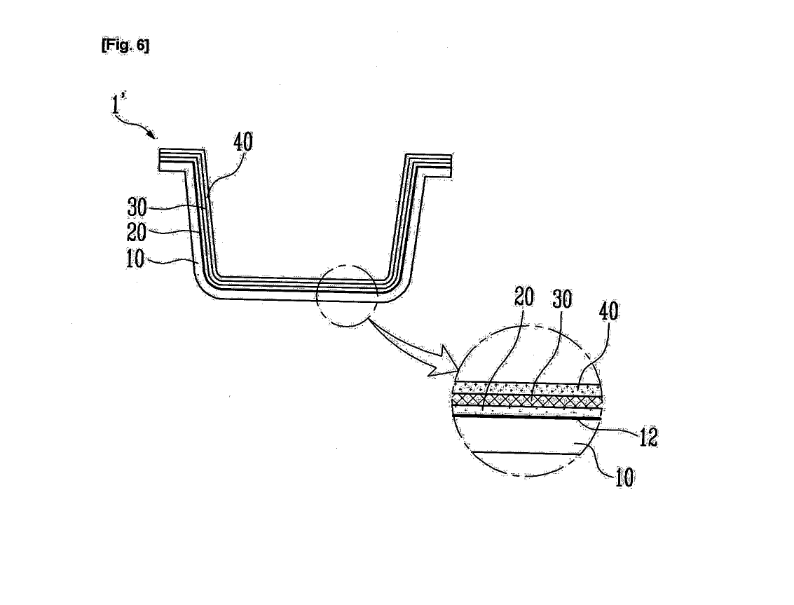

FIG. 6 is a sectional view showing a food container according to a second embodiment of the present invention.

Referring to FIG. 6, the food container 1′ according to the second embodiment of the present invention further includes a functional thin layer 40, as compared with the food container 1 according to the first embodiment of the present invention.

The functional thin layer 40 is used to add a desired surface property on the oxygen barrier thin layer 30, and may be formed on the oxygen barrier thin layer 30.

Here, the functional thin layer 40 may have surface properties such as hydrophobic and low-friction properties. Since the functional thin layer 40 also has compression energy, the functional thin layer 40 is preferably formed to have an optimum thickness.

HMDSO, fluorine incorporated diamond like carbon (F-DLC), or the like may be used as the functional thin layer 40 having the hydrophobic property.

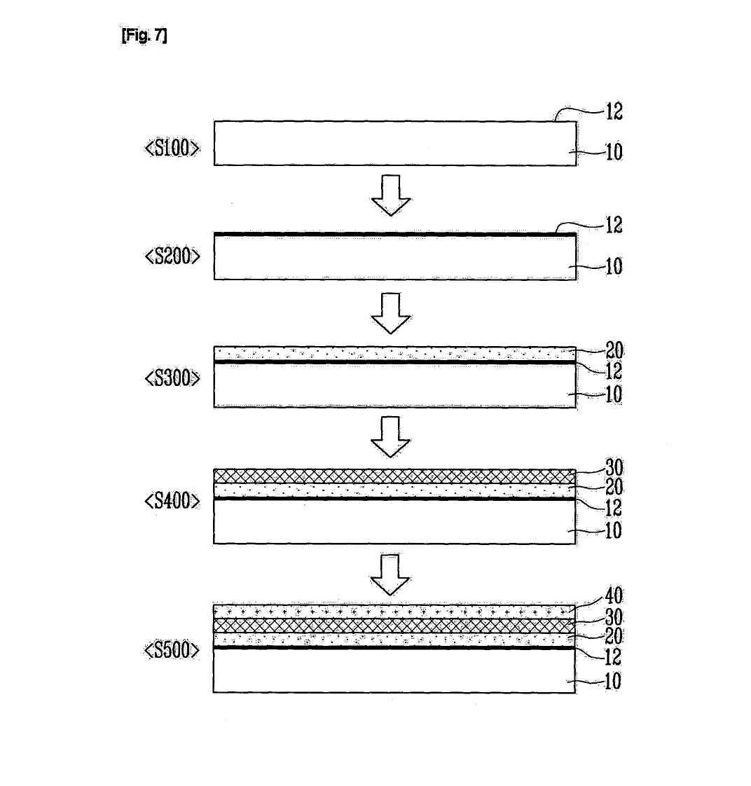

FIG. 7 is a sectional view illustrating a manufacturing method of the food container shown in FIG. 6.

Referring to FIG. 7, the manufacturing method of the food container 1′ according to the second embodiment of the present invention further includes a functional thin layer deposition step (S500), as compared with the manufacturing method of the food container 1 according to the first embodiment of the present invention.

The functional thin layer deposition step (S500) is performed after the oxygen barrier thin layer step (S400) is performed. In the functional thin layer deposition step (S500), a functional thin layer 40 is deposited on the oxygen barrier thin layer 30.

Like the buffer thin layer deposition step (S300) and the oxygen barrier thin layer deposition step (S400), the functional thin layer deposition step (S500) may be performed using plasma CVD.

Therefore, when a plasma state is formed by injecting the HMDSO gas into the chamber of the RF-CVD apparatus, the functional thin layer 40 is made of the pp-HMDSO material may be formed on the oxygen barrier thin layer 30.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

1. A food container having improved oxygen barrier properties, comprising:
a container made of a plastic material;
a buffer thin layer formed on a surface of the container and having a thickness of 5 to 30 nm; and
an oxygen barrier thin layer formed on the buffer thin layer.

2. The food container of claim 1, wherein the thickness of the oxygen barrier thin layer is 25 to 50 nm.

3. The food container of claim 1, wherein a plasma pretreatment is performed on the surface of the container so as to improve the adhesion between the surface of the container and the buffer thin layer.

4. The food container of claim 1, wherein the container is formed of polypropylene (PP).

5. The food container of claim 1, wherein the buffer thin layer is formed of hexamethyldisiloxane (HMDSO) or silicon (Si).

6. The food container of claim 1, wherein the oxygen barrier thin layer is formed of silicon oxide.

7. The food container of claim 1, further comprising a functional thin layer formed on the oxygen barrier thin layer.

8. The food container of claim 7, wherein the functional thin layer is formed of HMDSO or fluorine incorporated diamond like carbon (F-DLC).

9. A manufacturing method of a food container having oxygen barrier properties, the method comprising the steps of:
(a) preparing a container made of a plastic material;
(b) performing an oxygen plasma treatment on a surface of the container;
(c) depositing a buffer thin layer having a thickness of 5 to 30 nm on the surface of the container; and
(d) depositing an oxygen barrier thin layer on the buffer thin layer.

10. The method of claim 9, wherein the thickness of the oxygen barrier thin layer is 25 to 50 nm.

11. The method of claim 9, wherein the container is formed of PP.

12. The method of claim 9, wherein the steps (c) and (d) are performed through plasma chemical vapor deposition.

13. The method of claim 9, wherein the buffer thin layer is formed of HMDSO or Si.

14. The method of claim 9, wherein the oxygen barrier thin layer is formed of silicon oxide.

15. The method of claim 9, further comprising the step of (e) depositing a functional thin layer on the oxygen barrier thin layer.

16. The method of claim 15, wherein the functional thin layer is formed of HMDSO or F-DLC.
